(19) United States
(12) Patent Application Publication
(10) Pub. No.: US 2026/0056305 A1
(43) Pub. Date: Feb. 26, 2026

(54) SIGNAL PROCESSING DEVICE, FLYING OBJECT, EARTH STATION, SIGNAL PROCESSING SYSTEM, METHOD, AND PROGRAM

(71) Applicant: ArkEdge Space Inc., Tokyo (JP)

(72) Inventor: Shoichiro ADACHI, Koto-ku, Tokyo (JP)

(73) Assignee: ArkEdge Space Inc., Tokyo (JP)

(21) Appl. No.: 19/140,917

(22) PCT Filed: Nov. 27, 2024
(86) PCT No.: PCT/JP2024/042042

§ 371 Date: Jun. 18, 2025

(30) Foreign Application Priority Data
Apr. 30, 2024 (JP) 2024-073449

(51) Int. Cl. G01S 13/06; G01R 23/16; G01S 7/292; H03M 1/50

(52) U.S. Cl. CPC G01S 13/06; G01R 23/16; G01S 7/2927; H03M 1/50

(57) ABSTRACT

To provide a signal processing device or the like that can estimate a data sequence including a signal with an unknown frequency band from among received signals having a small S/N ratio.

A signal processing device 2A includes an A/D converter 215 that converts signals received by the flying object over a predetermined period of time by varying a time into a time-domain data sequence for each time, a fast Fourier transform (FFT) processing device 221 that performs FFT processing on the time-domain data sequence for each time with a plurality of different FFT points and outputs a frequency-domain FFT result data sequence at each FFT point, a correlation calculation device 222 that calculates a correlation between the frequency-domain FFT result data sequences at different times with the same FFT point for each segment based on a frequency resolution unit based on a sampling frequency of the A/D converter and the same FFT point and that performs the calculation for each of the plurality of different FFT points, and a data sequence selecting device 223 that selects a data sequence having the correlation equal to or greater than a threshold value.

### TECHNICAL FIELD

The present disclosure relates to a signal processing device, a flying object, an earth station, a signal processing system, a method, and a program for performing processing on signals of observed radio waves.

### BACKGROUND ART

A satellite system has been used in the related art to estimate a location of a radio wave transmission source (e.g., Non-Patent Documents 1 and 2). In such a satellite system of the related art, radio waves of a relatively narrow band are collected by a plurality of satellites, the resulting signals are downlink-transmitted to a ground station, and the ground station performs signal processing to estimate the location of the transmission source.

### CITATION LIST

### Non-Patent Document

[Non-Patent Document 1] “Determination of Geolocation of Radio Wave Source by Single Satellite Using Doppler Shift Rate”, Fucheng Guo, Space Electronic Reconnaissance Localization Theories and Methods, Chapter 6.3
[Non-Patent Document 2] “Determination of Geolocation of Radio Wave Source by Dual Satellite Based on TDOA and FDOA”, Fucheng Guo, Space Electronic Reconnaissance Localization Theories and Methods, Chapter 5.2

### SUMMARY OF THE INVENTION

### Technical Problem

When a flying object attempts to receive a signal with an unknown frequency band in order to monitor a signal such as a radio wave, the signal observation band needs to be set to a broadband. However, if the observation band is set to a broadband. noise increases and the S/N ratio deteriorates, so even if received broadband signals are converted into a data sequence of the frequency domain, it is hard to ascertain where unknown signals are included in the data sequence, and difficult to detect a signal included in the unknown signal from the broadband signals.

An embodiment of the present invention has been made to solve the above-described problem, and an object thereof is to estimate a data sequence including a signal with an unknown frequency band from among received signals having a small S/N ratio.

### Means for Solving the Problem

A signal processing device according to an embodiment of the present invention includes an A/D converter that converts signals received by one or more flying objects over a predetermined period of time by varying a time or a location into a time-domain data sequence for the corresponding time or location, a fast Fourier transform (FFT) processing device that performs FFT processing on the time-domain data sequence for the corresponding time or location with a plurality of different FFT points and outputs a frequency-domain FFT result data sequence at each FFT point, a correlation calculation device that calculates a correlation between the frequency-domain FFT result data sequences at different times or locations with the same FFT point for each segment based on a frequency resolution unit based on a sampling frequency of the A/D converter and the same FFT point and that performs the calculation for each of the plurality of different FFT points, and a data sequence selecting device that selects a data sequence having the correlation equal to or greater than a threshold value.

The data sequence may be a frequency-domain FFT result data sequence with an FFT point having the correlation equal to or greater than the threshold.

The data sequence may be the time-domain data sequence corresponding to the frequency-domain FFT result data sequence with an FFT point having the correlation equal to or greater than the threshold.

The correlation calculation device may calculate the correlation by multiplying, for a frequency-domain FFT result data sequence of each segment with the same FFT point, the frequency-domain FFT result data sequence of each segment at a first time by the complex conjugate of the frequency-domain FFT result data sequence of each segment at a second time and performing inverse FFT processing on the multiplication result.

The data sequence selecting device may select the data sequence by performing constant false alarm rate (CFAR) processing on the correlation.

A flying object according to an embodiment of the present invention includes any one of the signal processing devices described above, a storage device that stores the data sequence, and a transmitter that transmits the data sequence stored in the storage device to an earth station.

An earth station according to an embodiment of the present invention includes any one of the signal processing devices described above.

A signal processing system according to an embodiment of the present invention is a signal processing system with one or more flying objects and an earth station and includes an A/D converter that converts signals received by the one or more flying objects over a predetermined period of time by varying a time or a location into a time-domain data sequence for the corresponding time or location, a fast Fourier transform (FFT) processing device that performs FFT processing on the time-domain data sequence for the corresponding time or location with a plurality of different FFT points and outputs a frequency-domain FFT result data sequence at each FFT point, a correlation calculation device that calculates a correlation between the frequency-domain FFT result data sequences at different times or locations with the same FFT point for each segment based on a frequency resolution unit based on a sampling frequency of the A/D converter and the same FFT point and that performs the calculation for each of the plurality of different FFT points, and a data sequence selecting device that selects a data sequence having a correlation equal to or greater than a threshold value.

Each of the devices may be provided in one of the flying objects and the earth station.

Each of the devices may be distributed to the flying objects and the earth station.

A method for signal processing according to an embodiment of the present invention, in which one or more computers A/D convert signals received by one or more flying objects over a predetermined period of time by varying a time or a location into a time-domain data sequence for the corresponding time or location, perform fast Fourier transform (FFT) processing on the time-domain data sequence for the corresponding time or location with a plurality of different FFT points and output of a frequency-domain FFT result data sequence at each FFT point, calculate a correlation between the frequency-domain FFT result data sequences at different times or locations with the same FFT point for each segment based on a frequency resolution unit based on a sampling frequency of the A/D converter and the same FFT point, perform the calculation for each of the plurality of different FFT points, and select a data sequence having a correlation equal to or greater than a threshold value.

### Advantageous Effects of Invention

According to an embodiment of the present invention, a data sequence including a signal with an unknown frequency band can be estimated from among received signals having a small S/N ratio.

### BRIEF DESCRIPTION OF DRAWINGS

FIG. 1 is a diagram illustrating a configuration of a signal processing system according to a first embodiment.

FIG. 2 is a diagram illustrating a detailed configuration of a receiver.

FIG. 3 is a diagram illustrating the relationship between movement of a flying object (small satellite) and data sampling.

FIG. 4 is a diagram illustrating a detailed configuration of a digital signal processing device.

FIG. 5 is a diagram for explaining FFT processing of an FFT processing device.

FIG. 6 is a conceptual diagram when a frequency-domain FFT result data sequence at each FFT point is viewed in units of segments.

FIG. 7 is a diagram for explaining a correlation calculation method of a correlation calculation device.

FIG. 8 is a diagram for explaining a data selection processing of a data sequence selecting device.

FIG. 9 is an example of a flowchart of an operation of the signal processing system including the signal processing device according to the first embodiment.

FIG. 10 is a diagram illustrating a configuration of a signal processing system according to a second embodiment.

FIG. 11 is a diagram illustrating a positional relationship between a plurality of flying objects, an earth station, and a transmission source according to a third embodiment.

### DESCRIPTION OF EMBODIMENTS

A signal processing device, a flying object, an earth station, a signal processing system, a method, and a program according to embodiments of the present invention will be described with reference to the drawings.

### 1. First Embodiment

### 1-1. Configuration

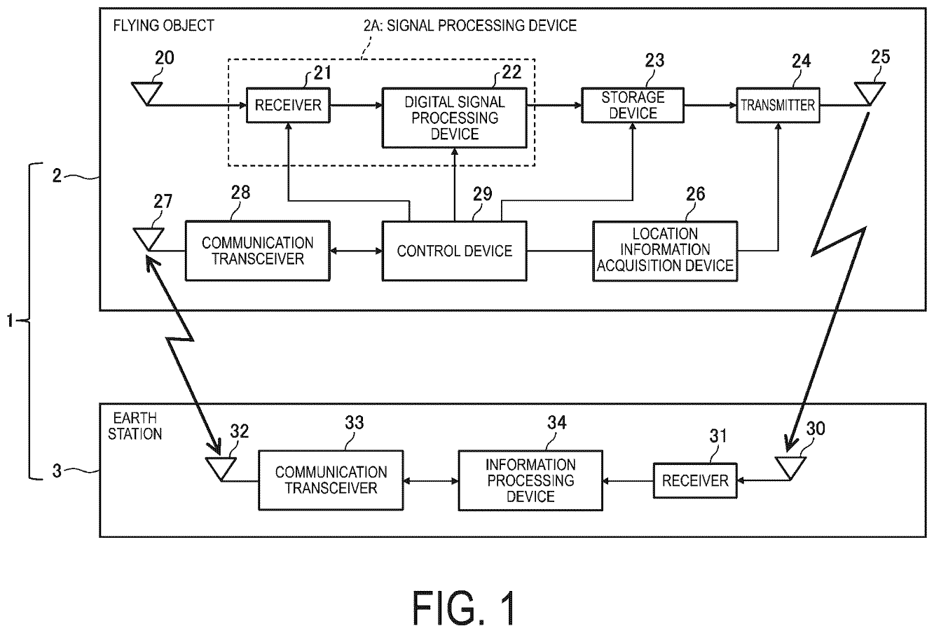

FIG. 1 is a diagram illustrating a configuration of a signal processing system according to a first embodiment. The signal processing system 1 illustrated in FIG. 1 is a system that receives signals such as radio waves and performs signal processing on the received signals. As will be described below, the signal processing system 1 estimates a data sequence including a signal with an unknown frequency band from among received signals. The signal processing system 1 can be used as a radio wave monitoring system.

The signal processing system 1 includes a flying object 2 and an earth station 3. The flying object 2 can receive signals such as radio waves, perform signal processing on the received signals, and transmit the result or the like to the earth station 3. The flying object 2 may be, for example, an artificial satellite or an aircraft. In the present specification, the flying object 2 is an artificial satellite, and more particularly, a small satellite. The small satellite may be, for example, a CubeSat satellite in a size of 1U to 6U, a W6U satellite, a 50 kg-class satellite, or the like. 1U is a size of 10 cm×10 cm×10 cm, and the sizes from 1U to 6U are 10 cm×10 cm×(10 cm to 60 cm). W6U represents a size of 10 cm×20 cm×30 cm. The 50 kg-class satellite is a satellite having a size of 55 cm×35 cm×55 cm. A small satellite can circulate around the earth on a satellite orbit. The satellite orbit may be, for example, a Low Earth Orbit (LEO), a middle Earth Orbit (MEO), or a Geostationary Earth Orbit (GEO), but is not particularly limited thereto.

The flying object 2 includes a receiving antenna 20, a receiver 21, a digital signal processing device 22, a storage device 23, a transmitter 24, a transmitting antenna 25, a location information acquisition device 26, a communication antenna 27, a communication transceiver 28, and a control device 29, and may include other components that realize various functions. The components may include a power supply subsystem that supplies power to devices mounted on the flying object 2 including a solar panel, a battery, and the like, an attitude control subsystem that controls attitudes of the flying object 2, a propulsion subsystem that propels the flying object 2, a thermal control subsystem that controls temperature ranges of the inside of the flying object 2, and the like.

The receiving antenna 20 is an antenna for receiving signals such as radio waves. Although radio waves referred to here may be electromagnetic waves having frequencies equal to or lower than 3 THz, for example, radio waves are not limited thereto. The receiving antenna 20 receives, for example, radio waves arriving from above the Earth. “Above the Earth” refers to, for example, above the ground and/or above the sea; however, radio waves that can be received by the receiving antenna 20 are not limited thereto. That is, a radio wave transmission source may include a facility installed on the ground, a mobile object that can move on the ground, a ship on the sea, a flying object in the air above the ground surface or the sea surface, and a spacecraft in outer space

The receiver 21 performs signal processing on received signals to convert the received signals into digital signals representing time-axis waveforms of the received signals. The digital signal processing device 22 is configured to include one or more computers and/or one or more processing circuits, and performs signal processing such as fast Fourier transform (FFT) on the signals output from the receiver 21 to select a data sequence. Detailed configurations of the receiver 21 and the digital signal processing device 22 will be described below. Note that a signal processing device 2A of the present embodiment can be configured by an A/D converter 215 and the digital signal processing device 22 of the receiver 21, which will be described below.

The storage device 23 is configured by a memory and/or a storage, and stores the data sequence selected by the digital signal processing device 22. The transmitter 24 transmits information including the data sequences stored in the storage device 23 and the information of the flying object 2 to the earth station 3 via the transmitting antenna 26. In one example, the information of the flying object 2 is satellite information including a location (altitude), a speed, and an acceleration of an artificial satellite, and is satellite information at a time corresponding to the selected data sequence. The transmitting antenna 25 is an antenna for transmitting signals including information. The information transmitted by the transmitter 24 and the transmitting antenna 25 is transmitted in a predetermined frequency band. The location information acquisition device 26 acquires location information of the flying object 2. The location information acquisition device 26 calculates a location (e.g., altitude), a speed, and an acceleration of the flying object 2 based on a signal from a global navigation satellite system (GNSS), for example. The calculated location, speed, and acceleration can be included in the information of the flying object 2 transmitted by the transmitter 24 and the transmitting antenna 25.

The communication antenna 27 is an antenna for receiving a command signal from the earth station 3 and transmitting a telemetry signal to the earth station 3. The command signal is a signal including command data for controlling the flying object 2. The command signal is a signal for the control device 29 to control each component, and is transmitted from the communication transceiver 28 to the control device 29. The telemetry signal is a signal including telemetry data indicating a state of the flying object 2. The telemetry data can include, for example, a location, a velocity, and an acceleration of the flying object 2. In order to avoid interference, the command signal and the telemetry signal are communicated in a frequency band different from that of the transmitter 24 and the transmitting antenna 25. The communication transceiver 28 demodulates the command signal received by the communication antenna 27, and outputs the demodulated signal to the control device 29. The communication transceiver 28 modulates the telemetry signal and transmits the modulated telemetry signal to the earth station 3 via the communication antenna 27.

The control device 29 is configured by one or more computers and/or one or more processing circuits and performs overall control of the flying object 2. For example, the control device 29 can control the receiver 21, the digital signal processing device 22, the storage device 23, the location information acquisition device 26, and the communication transceiver 28.

The earth station 3 is a system that communicates with the flying object 2. The earth station 3 may be fixedly installed on the ground, or may be equipped in a mobile object that can move on the ground, on the sea, or in the air above the ground surface or the sea surface.

The earth station 3 includes a receiving antenna 30, a receiver 31, a communication antenna 32, a communication transceiver 33, and an information processing device 34.

The receiving antenna 30 is an antenna for receiving information transmitted via the transmitter 24 and the transmitting antenna 25. The receiver 31 demodulates information received by the receiving antenna 30 and outputs the resultant information to the information processing device 34.

The communication antenna 32 is an antenna for transmitting command signals and receiving telemetry signals. The communication transceiver 33 modulates a control signal for the flying object 2 to generate and transmit a command signal. In addition, the communication transceiver 33 receives and demodulates a telemetry signal, and outputs the result to the information processing device 34.

The information processing device 34 is configured to include an input/output device, and a computer and/or a processing circuit, and generates a control signal for the flying object 2. In addition, the information processing device 34 estimates a location (e.g., latitude and longitude) of a radio wave transmission source based on information input from the receiver 31 and a Doppler shift rate. As such a location estimation method, a known method can be adopted, and for example, a method described in Non-Patent Document 1 can be used. The Doppler shift rate can be obtained from a time-domain data sequence at each time. Although the information processing device 34 of the present embodiment has a function of controlling the flying object 2 and a function of estimating a location of a radio wave transmission source, each of the functions may be configured based on a separate hardware configuration.

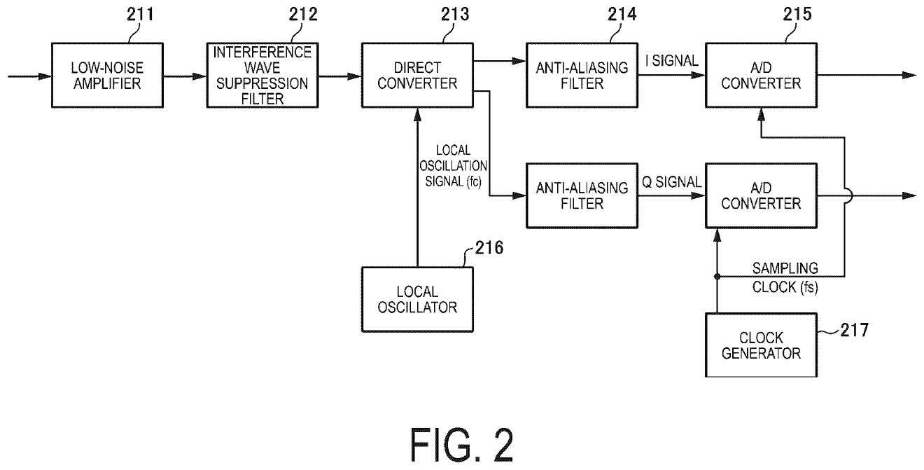

FIG. 2 is a diagram illustrating a detailed configuration of the receiver. The receiver 21 may be a heterodyne receiver, a direct-sampling receiver, or a direct-conversion receiver. The receiver 21 of the present embodiment is of a direct conversion type. The receiver 21 includes a low-noise amplifier 211, an interference wave suppression filter 212, a direct conversion 213, anti-aliasing filters 214, A/D converters 215, a local oscillator 216, and a clock generator 217.

The low-noise amplifier 211 amplifies a signal received by the receiving antenna 20 with suppressed noise. The interference wave suppression filter 212 is a filter that suppresses an interference wave from the signal input from the low-noise amplifier 211. The direct conversion 213 converts the frequency of the signal input from the interference wave suppression filter 212 into a low frequency to generate I and Q signals. Specifically, the direct conversion 213 mixes the signal input from the interference wave suppression filter 212 and a local oscillation signal from the local oscillator 216 to generate an in-phase signal (I signal) and a quadrature-phase signal (Q signal). The I signal and the Q signal are analog signals. The anti-aliasing filters 214 are provided for the I and Q signals, respectively, and are filters for removing aliases of the I and Q signals.

The A/D converters 215 are provided for the I and Q signals, respectively, and convert the I and Q signals which are analog signals into data sequences which are digital signals. Specifically, the A/D converter 215 generates the digital I and Q signals with a sampling clock having a sampling frequency fs from the clock generator 217. That is, the digital I and Q signals are time-domain data sequences sampled, quantized and encoded at the sampling frequency fs.

The local oscillator 216 generates a local oscillation signal and provides the signal to the direct conversion 213. The local oscillation signal is a signal having a local oscillation signal frequency that determines a center frequency fc. The local oscillator 216 can switch the center frequency fc based on a control signal from the control device 29. The clock generator 217 generates a sampling clock and provides the clock to the A/D converter 215. The sampling clock is a signal having a sampling frequency fs.

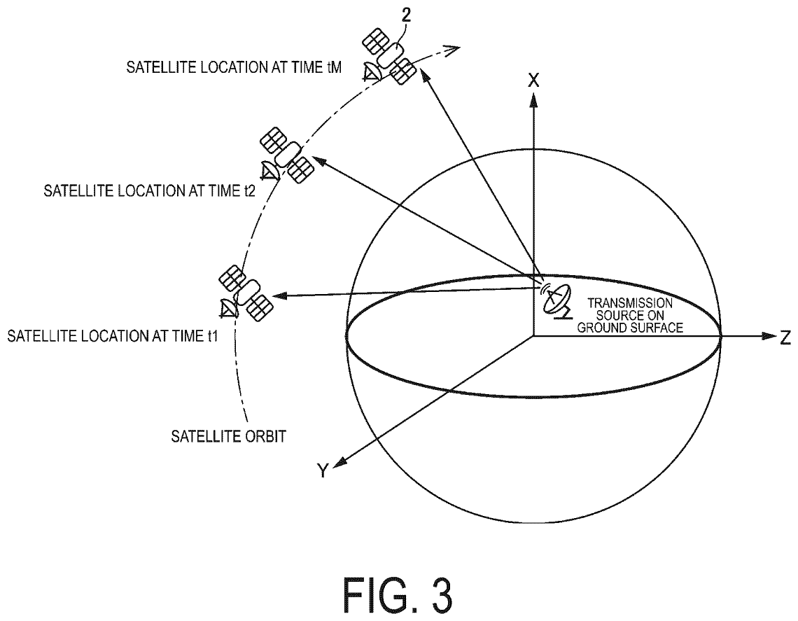

The relationship between radio wave collection and a time-domain data sequence generated from collected radio wave signals will be described with reference to FIG. 3. FIG. 3 is a diagram illustrating the relationship between movement of the flying object (small satellite) 2 and data sampling. As illustrated in FIG. 3, one example of radio wave collection is that one flying object 2 receives radio waves from different times ti (i is a natural number) over a predetermined period of time while the flying object 2 circulates a satellite orbit. For example, the flying object 2 receives a signal in the observation band having the center frequency fc and a bandwidth B at a time t1 for S seconds, and receives a signal in the observation band having the center frequency fc and the bandwidth B at a time t2 that is different from the time t1 for S seconds. In this way, the reception of radio waves can be repeated at different times in the same observation band. In addition, the flying object 2 can repeat the reception by changing the observation bands of the radio waves by switching the center frequency fc. The plurality of observation bands may or may not overlap with adjacent observation bands. In addition, the center frequency fc can be switched for each circulation each coverage area. Furthermore, the radio wave collection may be performed by orbiting the Earth a plurality of times to receive radio waves in a broadband or to receive radio waves in the entire coverage area.

The center frequency fc can be determined by the frequency of a local oscillation signal of the local oscillator 216. Since the bandwidth B is proportional to the sampling frequency fs, the bandwidth can be determined by using the sampling frequency fs of the A/D converter 215. Thus, since the bandwidth B can be set to be broader as the sampling frequency fs is higher, signals having a wider frequency band can be received, and signals with an unknown frequency band can be easily captured.

In the present specification, assuming that a signal received at each time ti for S seconds is identified as a signal of each time ti for convenience, the A/D converter 215 converts the signal of the time ti into a time-domain data sequence of the time ti. Assuming that the number of pieces of sample data for S seconds at the sampling frequency fs is K, the time-domain data sequence of each time ti includes digital I and Q signals in the time domain composed of K pieces of data. Note that the signal of each time ti input to the A/D converter 215 is a signal that has passed through each of the components 211 to 214. In this way, the A/D converter 215 converts the signals received by the flying object 2 over a predetermined period of time by varying the time into time-domain data sequences at each time.

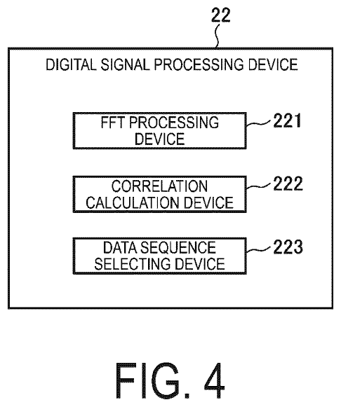

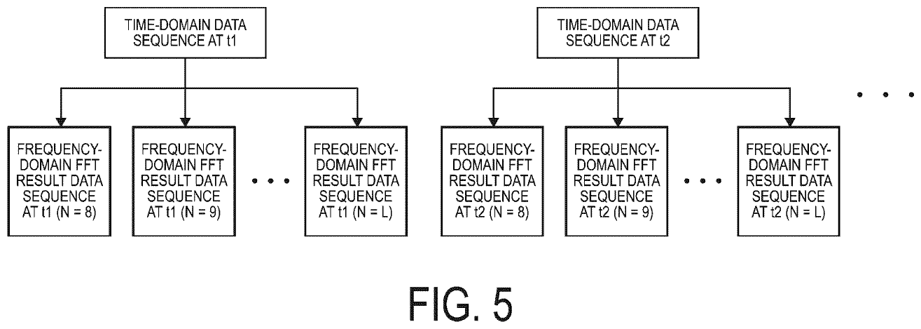

FIG. 4 is a diagram illustrating a detailed configuration of the digital signal processing device. The digital signal processing device 22 includes an FFT processing device 221, a correlation calculation device 222, and a data sequence selecting device 223. FIG. 5 is a diagram for explaining FFT processing of the FFT processing device.

As illustrated in FIG. 5, the FFT processing device 221 performs FFT processing on a time-domain data sequence at each time with a plurality of different fast Fourier transform (FFT) points, and outputs a frequency-domain FFT result data sequence at each FFT point. An FFT point is a sampling point, which is 2^{N} is a natural number, and may be a natural number of 8 or greater, for example, 8, 9, 10, . . . , L.

Here, it is assumed that the number of pieces of sample data K of the time-domain data sequence at each time is greater than the FFT point. For example, K=2^{M}, and M is a natural number satisfying M>N. The FFT processing device 221 divides the time-domain data sequence at each time by the FFT points 2^{N} and performs the FFT processing K/2^{N} times. Specifically, the FFT processing device 221 divides the time-domain data sequence at each time into K/2^{N} sets so that each set has 2 pieces of data, performs the FFT processing on each set, and obtains an FFT result (that is, a frequency-domain data sequence) of each set. Then, the FFT results of the sets are added, and the addition result is output as a frequency-domain FFT result data sequence, As illustrated in FIG. 5, since the FFT processing device 221 performs the FFT processing on the time-domain data sequence at each time with a plurality of different N (i.e., a plurality of different FFT points), the FFT processing device 221 outputs a plurality of frequency-domain FFT result data sequences for the time-domain data sequence at the time ti. For example, the FFT processing device 221 outputs frequency-domain FFT result data sequences for N=8, 9, 10, and the like through the FFT processing on the time-domain data sequence of the time t1. As illustrated in FIG. 5, a plurality of frequency-domain FFT result data sequences at different FFT points are derived from a time-domain data sequence at a time ti. Accordingly, the plurality of frequency-domain FFT result data sequences may be labeled with times ti and FFT points (N).

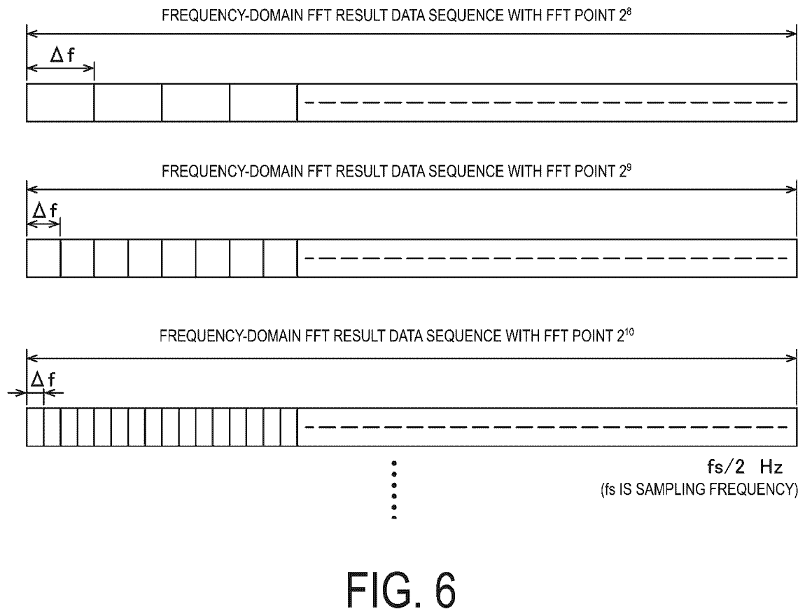

The correlation calculation device 222 calculates a correlation between frequency-domain FFT result data sequences at different times with the same FFT points for each segment in a frequency resolution unit. Then, the correlation calculation device 222 performs the calculation for each of a plurality of different FFT points. Here, the frequency resolution unit Δf is based on the sampling frequency fs of the A/D converter 215 and the same FFT point 2^{N}. Here, since Δf=fs/2^{N} and fs is constant, the frequency resolution unit Δf decreases as N increases. FIG. 6 is a conceptual diagram when frequency-domain FFT result data sequences at FFT points are viewed in units of segments. In the example of FIG. 6, frequency-domain FFT result data sequences at N=8, 9, 10, . . . at times ti are illustrated. As illustrated in FIG. 6, in the frequency-domain FFT result data sequences, the larger N is, the smaller the size of each segment, i.e., the frequency resolution unit Δf, is. In other words, by varying the FFT point, signal processing can be performed with various frequency resolutions, so signal processing that matches the frequency of radio waves of the radio wave transmission source can be performed.

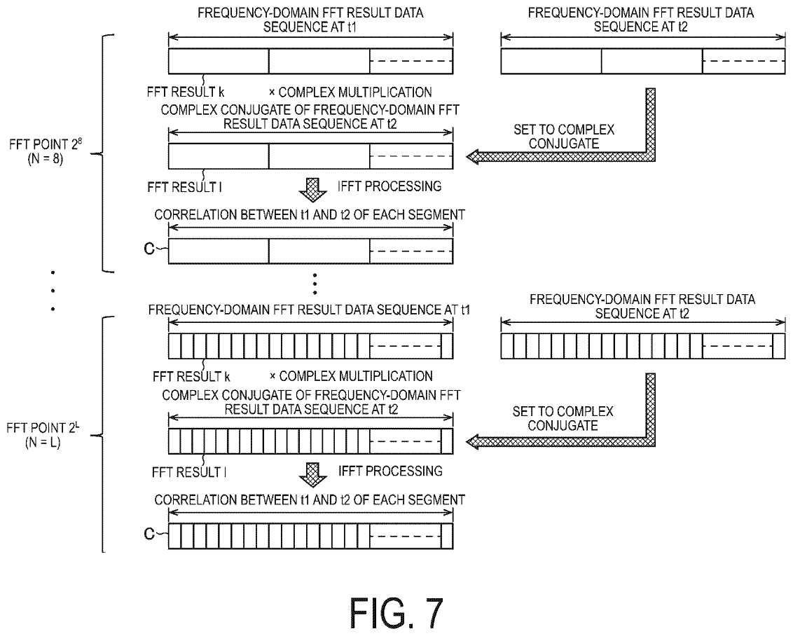

FIG. 7 is a diagram for explaining a correlation calculation method of the correlation calculation device. In the present embodiment, the correlation calculation device 222 multiplies the frequency-domain FFT result data sequence for each segment Δf at a time ti by the complex conjugate of the frequency-domain FFT result data sequence for each segment Δf at a time tj different from the time ti in the frequency-domain FFT result data sequence for each segment Δf with the same FFT point, and performs the inverse FFT processing on the multiplication result to calculate the correlation as illustrated in FIG. 7.

Specifically, assuming that the frequency-domain FFT result data sequence of each segment with the same FFT point is an FFT result k (k=0, 1, . . . , 2^{N}−1), the frequency-domain FFT result data sequence at each time is composed of a plurality of FFT results k (k=0, 1, . . . , 2^{N}−1). For example, the first segment of the frequency-domain FFT result data sequence at each time is FFT result 0, and the second segment thereof is FFT result 1. The correlation calculation device 222 calculates (FFT result k) at a time ti×(FFT result 1)* at a time tj (k, 1=0, 1, . . . , 2^{N}−1) and performs the inverse FFT processing on each multiplication result to obtain the correlation. A correlation is obtained for each segment. A correlation C in FIG. 7 is composed of correlations between segments.

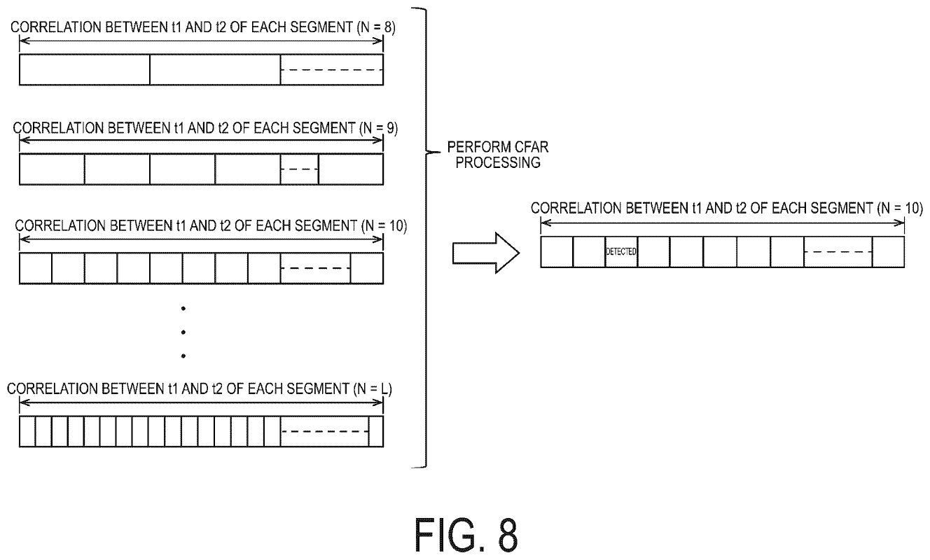

The data sequence selecting device 223 selects a data sequence whose correlation is equal to or greater than a threshold value. FIG. 8 is a diagram for explaining a data selection processing of the data sequence selecting device. As illustrated in FIG. 8, the data sequence selecting device 223 according to the present embodiment performs constant false alarm rate (CFAR) processing on the calculated correlation and performs signal detection. When a signal is detected, that is, when a correlation is equal to or greater than the threshold value, the signal matches the received signal band (the frequency band of the radio wave) and there is an integration effect. Although FIG. 8 illustrates an example in which one frequency band is detected, a plurality of bands can be detected for one data sequence. In this case, the presence of a plurality of radio wave transmission sources is estimated based on the detection of the plurality of bands. The CFAR processing may be well-known processing such as cell average CFAR or Weibull CFAR.

The data sequence selecting device 223 can cause the storage device 23 to store a data sequence having a correlation equal to or greater than the threshold value. That is, the data sequence selecting device 223 selects data sequences to be stored in the storage device 23 from a large number of data sequences depending on whether there is a correlation. The data sequences to be stored may be frequency-domain FFT result data sequences at the FFT point with a correlation equal to or greater than the threshold value, or may be time-domain data sequences corresponding to the frequency-domain FFT result data sequences at the FFT point with a correlation equal to or greater than the threshold value. Since the correlation is the result of data sequences at different times, the data sequences to be stored can be a pair of data sequences at different times. In one example, the data selecting device 223 causes the storage device 23 to store data sequences of the time t1 and the time t2 that are frequency-domain FFT result data sequences with the same FFT point having a correlation equal to or greater than the threshold value. In another example, the data selecting device 223 causes the storage device 23 to store the data sequences of the time t1 and the time t2 that are time-domain data sequences corresponding to frequency-domain FFT result data sequences with the same FFT point having a correlation equal to or greater than the threshold value. The threshold value can be set as appropriate.

### 1-2. Operation

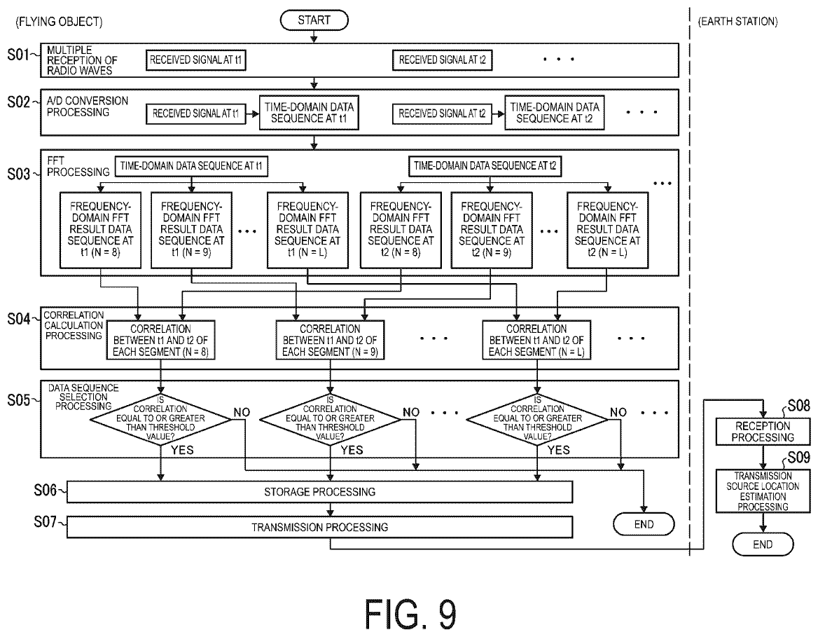

FIG. 9 is an example of a flowchart of an operation of the signal processing system including the signal processing device according to the present embodiment. As shown in FIG. 9, the flying object 2 performs radio wave reception multiple times (S01: reception of radio waves multiple times). For example, the flying object 2 which is an artificial satellite receives radio waves at a discrete time ti (i is a natural number) for S seconds in an observation band having a center frequency fc and a bandwidth B while tracing a satellite orbit. In the present embodiment, the received signals undergo various types of processing by the components 211 to 214 and 216 of the receiver 21.

Next, the A/D converter 215 performs A/D conversion processing on each signal of S01 at the sampling frequency fs to generate a time-domain data sequence at each time ti (S02: A/D conversion processing). In one example, the number K of pieces of sample data of the time-domain data sequence at each time is 2^{M}.

The FFT processing device 221 performs the FFT processing on the time-domain data sequences at respective times with a plurality of different FFT points to generate frequency-domain FFT result data sequences having the times and FFT points as parameters (S03: FFT processing). Specifically, the FFT processing device 221 sequentially performs the FFT processing on the time-domain data sequences at the respective time for each FFT point 2^{N}, and repeats this processing K/2^{N} times. In other words, assuming that the number of 2^{N} pieces of data of the time-domain data sequences at the respective times is one set, the time-domain data sequences at the respective times are a collection of K/2^{N} sets, and the FFT processing is performed on each of the sets. For example, when M=14 and N=8, there are 2¹⁴/2⁸=64 sets, and thus the FFT processing is performed 64 times. The horizontal axis for the FFT result of each set is frequency, and the FFT processing device 221 adds the FFT results of the sets at the respective times, and sets the addition result as a frequency-domain FFT result data sequence at each time. In this way, frequency-domain FFT result data sequences with a plurality of different FFT points at the respective times are obtained in S03.

The correlation calculation device 222 performs correlation calculation processing (S04: correlation calculation processing). That is, the correlation calculation processing is processing of calculating a correlation between frequency-domain FFT result data sequences at different times with the same FFT point for each segment and executing the calculation for each of a plurality of different FFT points. The segment is a frequency resolution unit Δf, and Δf=sampling frequency fs/FFT point 2^{N}. Since fs is constant, the larger N is, the smaller Δf is. Assuming that the frequency-domain FFT result data sequence of each segment is FFT result k (k=0, 1, . . . 2^{N}−1), the correlation calculation device 222 multiplies each FFT result k at a time ti by (FFT result 1)* at a time tj (k, 1=0, 1, . . . 2^{N}−1) and performs the inverse FFT processing on each multiplication result to obtain a correlation.

The data selecting device 223 performs a data sequence selection processing of selecting a data sequence based on the correlation obtained in S04 (S05: data sequence selection processing). Here, the data selecting device 223 regards a data sequence having a correlation equal to or greater than a threshold value as a data sequence to be stored in the storage device 23 and selects a data sequence having a correlation less than the threshold value as a data sequence not to be stored in the storage device 23.

The data sequences having a correlation equal to or greater than the threshold value are stored in the storage device 23 (S06: storage processing). Then, the transmitter 24 reads the data sequences having a correlation equal to or greater than the threshold value from the storage device 23, modulates the data sequences, and transmits the modulated data sequence to the earth station 3 via the transmitting antenna 25 (S07: transmission processing). The transmitter 24 transmits the state information of the flying object 2 (for example, the location, speed, and acceleration of the flying object 2) at the time corresponding to the data sequences to the earth station 3. This transmission may be performed together with or separately from the transmission of the data sequences.

In the earth station 3, the receiver 31 receives the transmitted data sequence and the state information of the flying object 2 via the receiving antenna 30 (S08: reception processing), and the information processing device 34 performs a transmission source location estimation processing for estimating the location of the radio wave transmission source based on the data sequence, the state information of the flying object 2, and the Doppler shift rate (S09: transmission source location estimation processing).

As described above, by performing the FFT processing with a plurality of different FFT points, it is possible to diversify the data sequence of the frequency domain; furthermore, to obtain the correlation with various frequency resolution units Δf, and to select the data sequence necessary for location estimation analysis even if the transmission is in an unknown frequency band. The correlation calculation processing and the data sequence selection processing can be collectively referred to as a matching band detection processing.

### 1-3. Actions and Effects

(1) The signal processing device 2A of the present embodiment includes the A/D converter 215 that converts signals received by the flying object over a predetermined period of time by varying a time into a time-domain data sequence for each time, the fast Fourier transform (FFT) processing device 221 that performs the FFT processing on the time-domain data sequence at each time with a plurality of different FFT points and outputs a frequency-domain FFT result data sequence at each FFT point, the correlation calculation device 222 that calculates a correlation between the frequency-domain FFT result data sequences at different times with the same FFT point for each segment based on the frequency resolution unit based on the sampling frequency of the A/D converter 215 and the same FFT point and that performs the calculation for each of the plurality of different FFT points, and the data sequence selecting device 223 that selects a data sequence having the correlation equal to or greater than the threshold value.

Thus, a data sequence including a signal with an unknown frequency band can be estimated from among received signals having a small S/N ratio. This estimated data sequence can be used to estimate the location (e.g., latitude or longitude) of the transmission source of the unknown signal.

(2) The flying object 2 according to the present embodiment includes the signal processing device 2A, the storage device 23 that stores data sequences, and the transmitter 24 that transmits a data sequence stored in the storage device 23 to a ground station.

Thus, since data sequences required for signal detection of unknown signals can be narrowed down and provided to the earth station 3, a large-capacity storage device or a data line may not be required, different from the case in which all data sequences of received signals are stored or transmitted to the earth station 3. In particular, even if the flying object 2 is a small satellite with a limited loading capacity, the flying object 2 can be utilized for signal detection of unknown signals. That is, in general, in order to capture a signal of an unknown transmission source, signals received in a broadband need to be sampled, and thus the sampling frequency of the A/D converter needs to be increased. However, it is difficult for such a small satellite to increase the sampling frequency because the storage capacity for storing sampled data and the transmission amount of downlink transmission of the data to the ground station are restricted. On the other hand, since only a data sequence necessary for signal detection is provided to the earth station 3 according to the present embodiment, there is an advantage that the above-mentioned restriction is not imposed.

### 2. Second Embodiment

A second embodiment will be described. Only configurations different from those of the first embodiment will be described, and the description of the same configuration will be omitted. In the second embodiment, the digital signal processing performed in the first embodiment is set to be performed by the earth station 3.

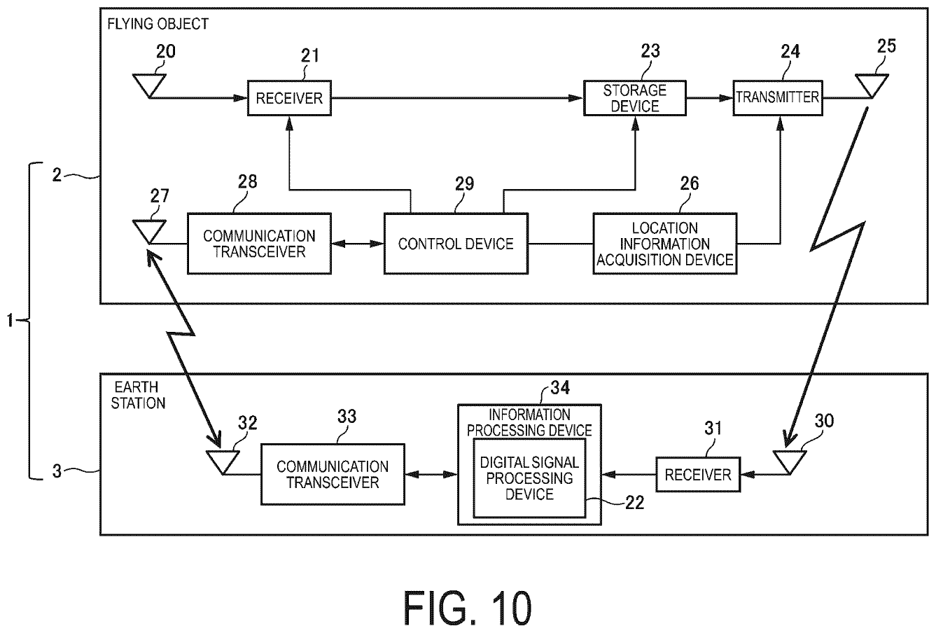

FIG. 10 is a diagram illustrating a configuration of a signal processing system according to the second embodiment. In the second embodiment, the digital signal processing device 22 is provided in the earth station 3, instead of the flying object 2, as illustrated in FIG. 10. For this reason, in the flying object 2, the digital I and Q signals from the receiver 21 are stored in the storage device 23, and the signals are transmitted to the earth station 3 via the transmitter 24 and the transmitting antenna 25.

In the earth station 3, the digital I and Q signals from the flying object 2 are received by the receiving antenna 30 and the receiver 31, and the received signals are input to the information processing device 34. The information processing device 34 according to the present embodiment includes the digital signal processing device 22, and performs the FFT processing, the correlation calculation processing, the data selection processing, and the transmission source location estimation processing as in the first embodiment.

### 3. Third Embodiment

A third embodiment will be described. Only configurations different from those of the second embodiment will be described, and the description of the same configuration will be omitted. In the third embodiment, radio waves are received by a plurality of flying objects 2, unlike in the first and second embodiments.

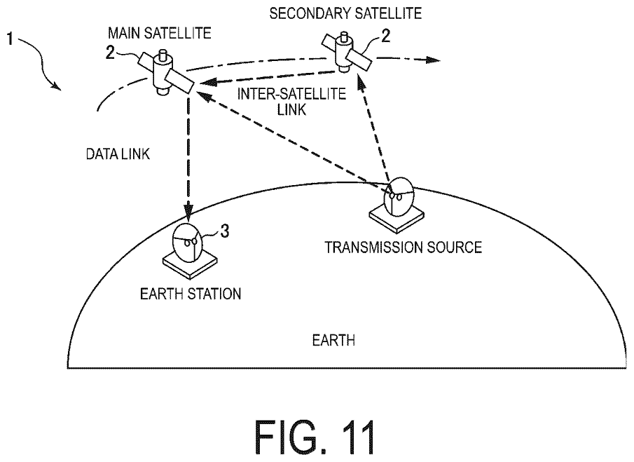

FIG. 11 is a diagram illustrating a positional relationship between a plurality of flying objects, an earth station, and a transmission source according to a third embodiment. A signal processing system 1 of the present embodiment includes two flying objects 2, one of which is a main satellite and the other of which is a secondary satellite. The flying objects 2 receive radio waves at the same time, cause the storage device 23 to store digital I and Q signals processed for A/D conversion at the same sampling frequency fs in the respective receiver 21, and transmit the signals to the earth station 3 via their respective transmitters 24 and transmitting antennas 25.

In the earth station 3, the digital I and Q signals from the flying object 2 are received by the receiving antenna 30 and the receiver 31, and the received signals are input to the information processing device 34. The digital signal processing device 22 of the information processing device 34 performs the FFT processing, the correlation calculation processing, the data selection processing, and the transmission source location estimation processing, as in the first and second embodiments. However, in the transmission source location estimation processing, the location estimation is performed in consideration of the delay of downlink data between the main satellite and the secondary satellite and the Doppler correlation.

While one flying object 2 calculates a correlation between different times in the second embodiment, the correlation at different locations is calculated using signals received by the main satellite and the secondary satellite at the same time in the third embodiment. That is, a time-domain data sequence at each time and a frequency-domain FFT result data sequence at each time in the second embodiment are replaced with a time-domain data sequence at each location and a frequency-domain FFT result data sequence at each location in the present embodiment.

### 4. Other Embodiments

Other embodiments will be described. Only configurations different from those of the above-described embodiments will be described, and the description of the same configuration will be omitted.

In another embodiment, a configuration of the receiver 21 and a configuration of the digital signal processing device 22 may be provided in either the flying object 2 or the earth station 3, or may be distributed to the flying object 2 and the earth station 3. That is, the A/D converter 215, the FFT processing device 221, the correlation calculation device 222, and the data sequence selecting device 223 may be provided in either the flying object 2 or the earth station 3.

The signal processing device according to an embodiment of the present invention may include at least the digital signal processing device 22, and may not include the A/D converter 215, unlike the signal processing device 2A of the first embodiment.

In another embodiment of the present invention, a program for realizing the functions of the embodiments of the present invention described above and the processing shown in the flowcharts and a computer-readable storage medium storing the program can be provided. In addition, in another embodiment, a method for realizing the functions of the embodiments of the present invention described above and processing shown in the flowcharts can be provided. In addition, in another embodiment, a server that can supply a computer with the program for realizing the functions of the embodiments of the present invention described above and the processing shown in the flowcharts can be provided. In addition, in another embodiment, a virtual machine that realizes the functions of the embodiments of the present invention described above and the processing shown in the flowcharts can be provided.

In the processing or operations described above, the processing or operations can be modified freely as long as there is no occurrence of contradiction in the processing or operations such as using data that is not yet supposed to be used in a corresponding step. In addition, each embodiment described above is exemplified for describing the present invention, and the present invention is not limited to those examples. The present invention may be implemented in various forms without departing from the scope thereof.

### Reference Signs List

1 Signal processing system
2 Flying object
20 Receiving antenna
21 Receiver
211 Low-noise amplifier
212 Interference wave suppression filter
213 Direct conversion
214 Anti-aliasing filter
215 A/D converter
216 Local oscillator
217 Clock generator
22 Digital signal processing device
23 Storage device
24 Transmitter
25 Transmitting antenna
26 Location information acquisition device 26
27 Communication antenna
28 Communication transceiver 28
29 Control device
3 Earth station
30 Receiving antenna
31 Receiver
32 Communication antenna
33 Communication transceiver
34 Information processing device

1. A signal processing device comprising:
an A/D converter configured to convert signals received by one or more flying objects over a predetermined period of time by varying a time or a location into a time-domain data sequence for the corresponding time or location, the time-domain data sequence having a predetermined number of pieces of data;
a fast Fourier transform (FFT) processing device configured to divide the time-domain data sequence for the corresponding time or location into sets equal in number obtained by dividing the predetermined number of pieces of data by an FFT point, perform FFT processing on each of the sets, add an FFT result of each of the sets at the FFT point, and output the addition result as a frequency-domain FFT result data sequence at the FFT point, the FFT processing device performing the FFT processing, the addition, and the output at each of a plurality of different FFT points;
a correlation calculation device configured to calculate, for a frequency-domain FFT result data sequence with the same FFT point for each segment based on a frequency resolution unit based on a sampling frequency of the A/D converter and the same FFT point, a correlation by multiplying a frequency-domain FFT result data sequence of each segment at a first time by a complex conjugate of a frequency-domain FFT result data sequence of each segment at a second time, or multiplying a frequency-domain FFT result data sequence of each segment at a first location by a complex conjugate of a frequency-domain FFT result data sequence of each segment at a second location, and performing inverse FFT processing on the multiplication result, the correlation calculation device performing the calculation for each of the plurality of different FFT points; and
a data sequence selecting device configured to select a data sequence having the correlation equal to or greater than a threshold value, the data sequence being a pair of frequency-domain FFT result data sequences between different times or different locations having the correlation equal to or greater than the threshold value at the same FFT point and in the same segment, or a pair of time-domain data sequences corresponding to the pair of frequency-domain FFT result data sequences.

2. The signal processing device according to claim 1, wherein the data sequence selecting device selects the data sequence by performing constant false alarm rate (CFAR) processing on the correlation.

3. The signal processing device according to claim 1, wherein the signals include signals received by the one or more flying objects at varying center frequencies.

4. The signal processing device according to claim 1, further comprising:
a receiver provided in each of the one or more flying objects and configured to receive signals in observation bands each having a predetermined center frequency and a predetermined bandwidth over a predetermined period of time by varying a time and a location, and to receive the signals in different observation bands by shifting the center frequency,
wherein the A/D converter converts the received signals into time-domain data sequence for the corresponding time or location for each of the observation bands.

5. A flying object comprising:
the signal processing device according to claim 1;
a storage device configured to store the data sequence; and
a transmitter configured to transmit the data sequence stored in the storage device to an earth station.

6. An earth station comprising the signal processing device according to claim 1.

7. A signal processing system with one or more flying objects and an earth station, the signal processing system comprising:
an A/D converter configured to convert signals received by the one or more flying objects over a predetermined period of time by varying a time or a location into a time-domain data sequence for the corresponding time or location, the time-domain data sequence having a predetermined number of pieces of data;
a fast Fourier transform (FFT) processing device configured to divide the time-domain data sequence for the corresponding time or location into sets equal in number obtained by dividing the predetermined number of pieces of data by an FFT point, perform FFT processing on each of the sets, add an FFT result of each of the sets at the FFT point, and output the addition result as a frequency-domain FFT result data sequence at the FFT point, the FFT processing device performing the FFT processing, the addition, and the output at each of a plurality of different FFT points;
a correlation calculation device configured to calculate, for a frequency-domain FFT result data sequence with the same FFT point for each segment based on a frequency resolution unit based on a sampling frequency of the A/D converter and the same FFT point, a correlation by multiplying a frequency-domain FFT result data sequence of each segment at a first time by a complex conjugate of a frequency-domain FFT result data sequence of each segment at a second time, or multiplying a frequency-domain FFT result data sequence of each segment at a first location by a complex conjugate of a frequency-domain FFT result data sequence of each segment at a second location, and performing inverse FFT processing on the multiplication result, the correlation calculation device performing the calculation for each of the plurality of different FFT points; and
a data sequence selecting device configured to select a data sequence having the correlation equal to or greater than a threshold value, the data sequence being a pair of frequency-domain FFT result data sequences between different times or different locations having the correlation equal to or greater than the threshold value at the same FFT point and in the same segment, or a pair of time-domain data sequences corresponding to the pair of frequency-domain FFT result data sequences.

8. The signal processing system according to claim 7, wherein each of the devices is provided in either the flying objects or the earth station.

9. The signal processing system according to claim 7, wherein each of the device is distributed in the flying objects and the earth station.

10. A method for signal processing, wherein one or more computers:
A/D convert signals received by one or more flying objects over a predetermined period of time by varying a time or a location into a time-domain data sequence for the corresponding time or location, the time-domain data sequence having a predetermined number of pieces of data;
divide the time-domain data sequence for the corresponding time or location into sets equal in number obtained by dividing the predetermined number of pieces of data by a fast Fourier transform (FFT) point, perform FFT processing on each of the sets, add an FFT result of each of the sets at the FFT point, output the addition result as a frequency-domain FFT result data sequence at the FFT point, and perform the FFT processing, the addition, and the output at each of a plurality of different FFT points;
calculate, for a frequency-domain FFT result data sequence with the same FFT point for each segment based on a frequency resolution unit based on a sampling frequency of the A/D conversion and the same FFT point, a correlation by multiplying a frequency-domain FFT result data sequence of each segment at a first time by a complex conjugate of a frequency-domain FFT result data sequence for each segment at a second time, or multiplying a frequency-domain FFT result data sequence for each segment at a first location by a complex conjugate of a frequency-domain FFT result data sequence for each segment at a second location, and performing inverse FFT processing on the multiplication result, and perform the calculation for each of the plurality of different FFT points; and
select a data sequence having the correlation equal to or greater than a threshold value, the data sequence being a pair of frequency-domain FFT result data sequences between different times or different locations having the correlation equal to or greater than the threshold value at the same FFT point and in the same segment, or a pair of time-domain data sequences corresponding to the pair of frequency-domain FFT result data sequences.

11. A non-transitory computer readable medium storing a program causing one or more computers to execute the method according to claim 10.
